(19) United States
(12) Patent Application Publication
(10) Pub. No.: US 2012/0118347 A1
(43) Pub. Date: May 17, 2012

(54) THERMOELECTRIC CONVERSION MATERIAL

(75) Inventors: Yuichi Hiroyama, Ibaraki (JP); Hiroshi Kishida, Ibaraki (JP)

(73) Assignee: SUMITOMO CHEMICAL COMPANY, LIMITED, Chuo-ku, Tokyo (JP)

(21) Appl. No.: 13/322,940

(22) PCT Filed: May 28, 2010
(86) PCT No.: PCT/JP2010/059482

§ 371 Date: Feb. 3, 2012

(30) Foreign Application Priority Data
Jun. 4, 2009 (JP) 2009-134835

(51) Int. Cl. H01L 35/32; H01B 1/08; H01L 35/14

(52) U.S. Cl. 136/224; 252/519.14

(57) ABSTRACT

A thermoelectric conversion material includes a complex oxide containing Zn, Al, Ga, and B. The thermoelectric conversion material is one in which a ratio of a molar amount of B to a total molar amount of Zn, Al, Ga, and B is not less than 0.0001 and not more than 0.01. The thermoelectric conversion material is one in which the relative density of the complex oxide is not less than 95% The thermoelectric conversion material is one in which at least a part of a surface of the complex oxide is coated with a film. A thermoelectric conversion module is provided with a plurality of n-type thermoelectric conversion materials, a plurality of p-type thermoelectric conversion materials, and a plurality of electrodes electrically serially connecting the p-type thermoelectric conversion materials and the n-type thermoelectric conversion materials in an alternate arrangement, and at least one material of the plurality of n-type thermoelectric conversion materials is the aforementioned thermoelectric conversion material.

### TECHNICAL FIELD

The present invention relates to a thermoelectric conversion material. More particularly, the invention relates to a thermoelectric conversion material containing an oxide.

### BACKGROUND ART

The thermoelectric power generation is electric power generation by conversion of thermal energy to electric energy by making use of a phenomenon of generation of voltage (thermoelectric power) with a temperature difference given to thermoelectric conversion materials, i.e., the Seebeck effect. Since the thermoelectric power generation allows use of a variety of exhaust heat, such as geothermal heat and heat from incinerators, as thermal energy, it is expected as environment conservation type power generation that can be put into practical use.

An efficiency of conversion from thermal energy to electric energy, of a thermoelectric conversion material (which will be sometimes referred to as “energy conversion efficiency”) is dependent upon the value of performance index (Z) of the thermoelectric conversion material. The value of performance index (Z) is a value determined by the formula below, using the value of Seebeck coefficient (α) of the thermoelectric conversion material, the value of electric conductivity (σ), and the value of thermal conductivity (κ). The larger the value of performance index (Z) of the thermoelectric conversion material, the higher the energy conversion efficiency of the thermoelectric conversion material. Furthermore, α²×σ in the below formula is called power factor and the value of this power factor is also used as an index to indicate the thermoelectric conversion characteristic.

Z=α²×σ/κ

The thermoelectric conversion materials include p-type thermoelectric conversion materials with positive values of the Seebeck coefficient, and n-type thermoelectric conversion materials with negative values of the Seebeck coefficient. Usually, the thermoelectric power generation is implemented using a thermoelectric conversion module provided with a plurality of p-type thermoelectric conversion materials, a plurality of n-type thermoelectric conversion materials, and a plurality of electrodes electrically serially connecting these materials in an alternate arrangement.

These thermoelectric conversion materials are generally classified, particularly, into materials made of metal and materials made of oxide. The materials made of oxide are suitable for use in a high-temperature atmosphere. Examples of the materials made of metal include silicide-based materials such as β-FeSi₂, and examples of the materials made of oxide include zinc oxide-based materials.

A zinc oxide-based thermoelectric conversion material is a thermoelectric conversion material in which part of Zn in ZnO is replaced with Al, which is disclosed in JP8-186293A, and in an example thereof, ZnO and Al₂O₃ are mixed, the mixture is molded into a compact, and thereafter the compact is sintered at around 1400° C. to obtain the thermoelectric conversion material. Non-patent Literature (Kiyoshi Yamamoto et al., “Proceedings at 5th Annual Meeting of The Thermoelectrics Society of Japan (TSJ2008)” p 18 (2008)) discloses the thermoelectric conversion material in which ZnO is codoped with Al and Ga to replace part of Zn.

However, if the sintering temperature exceeds 1300° C. during manufacture of the aforementioned conventional zinc oxide type thermoelectric conversion material, Zn will evaporate because of high vapor pressure of zinc and it is therefore difficult to control the composition of the objective and also difficult to perform the maintenance of a manufacturing system. It is also found that when the sintering is carried out at a reduced temperature of around 1200° C., the resultant sintered body increases its surface resistance with processing such as cutting and polishing thereof, so as to induce reduction of power in the thermoelectric power generation.

### DISCLOSURE OF THE INVENTION

An object of the present invention is to provide a thermoelectric conversion material having a small value of surface resistance, being resistant to increase in surface resistance during processing, and having a large value of power factor.

The present invention provides the means described below.

<1> A thermoelectric conversion material comprising a complex oxide containing Zn, Al, Ga, and B.
<2> The thermoelectric conversion material of <1> wherein the ratio of a molar amount of B to a total molar amount of Zn, Al, Ga, and B is not less than 0.0001 and not more than 0.01.
<3> The thermoelectric conversion material of <1> or <2> wherein the ratio of a molar amount of Al to the total molar amount of Zn, Al, Ga, and B is not less than 0.001 and not more than 0.1.
<4> The thermoelectric conversion material of any one of <1> to <3> wherein the ratio of a molar amount of Ga to the total molar amount of Zn, Al, Ga, and B is not less than 0.001 and not more than 0.1.
<5> The thermoelectric conversion material of any one of <1> to <4> wherein the relative density of the complex oxide is not less than 95%.
<6> The thermoelectric conversion material of any one of <1> to <5> wherein at least a part of a surface of the complex oxide is coated with a film.
<7> A thermoelectric conversion module comprising: a plurality of n-type thermoelectric conversion materials; a plurality of p-type thermoelectric conversion materials; and a plurality of electrodes electrically serially connecting the plurality of p-type thermoelectric conversion materials and the plurality of n-type thermoelectric conversion materials in an alternate arrangement, wherein at least one material of the plurality of n-type thermoelectric conversion materials is the thermoelectric conversion material of any one of <1> to <6>.

### BRIEF DESCRIPTION OF DRAWINGS

FIG. 1 is a cross-sectional view of an example of the thermoelectric conversion module using thermoelectric conversion materials according to an embodiment of the present invention.

FIG. 2 is a cross-sectional view of another example of the thermoelectric conversion module using thermoelectric conversion materials according to an embodiment of the present invention.

### REFERENCE SIGNS LIST

1 thermoelectric conversion module, 2 first substrate, 3 p-type thermoelectric conversion materials, 4 n-type thermoelectric conversion materials, 6 second electrodes, 7 second substrate, 8 first electrodes, 9 joint materials, 10 thermoelectric conversion materials, 12 support frame, 12a through holes, and a1 and a2 end faces of thermoelectric conversion materials opposing to electrodes.

### Description of Embodiments

### <Thermoelectric Conversion Material of the Present Invention>

A thermoelectric conversion material of the present invention comprises a complex oxide containing Zn, Al, Ga, and B. The complex oxide in the present invention is preferably one in which part of Zn in ZnO is replaced with the three elements of Al, Ga, and B.

In terms of more suppressing the increase in surface resistance during processing of the thermoelectric conversion material, the ratio of the molar amount of B to the total molar amount of Zn, Al, Ga, and B of the complex oxide in the present invention is preferably not less than 0.0001 and not more than 0.01 and, in terms of achieving more increase in value of power factor of the thermoelectric conversion material, the ratio is more preferably not less than 0.0001 and not more than 0.001.

The ratio of the molar amount of Al to the total molar amount of Zn, Al, Ga, and B of the complex oxide in the present invention is preferably not less than 0.001 and not more than 0.1. The ratio of the molar amount of Ga to the total molar amount of Zn, Al, Ga, and B of the complex oxide in the present invention is preferably not less than 0.001 and not more than 0.1.

The thermoelectric conversion material of the present invention is used mainly in the form of powder, a sintered body, or a thin film and, particularly, in the form of a sintered body. When the thermoelectric conversion material of the present invention is used in the form of the sintered body, the sintered body is formed in appropriate shape and size in a thermoelectric conversion module and it is used as the thermoelectric conversion material. Specific examples of stereoscopic shapes applicable herein include prismatic shapes like a rectangular parallelepiped, platelike shapes, and cylindrical shapes. It is common practice to use the thermoelectric conversion material consisting of the sintered body after its end faces or surfaces opposing to electrodes in the below-described thermoelectric conversion module are polished.

### <Manufacturing Method of Thermoelectric Conversion Material>

The complex oxide in the present invention can be manufactured by calcining a mixture of raw material compounds. Specifically, it can be manufactured by weighing respective compounds each containing Zn, Al, Ga, or B corresponding to the complex oxide in the present invention, so as to achieve a prescribed composition, mixing them, and then calcining the resultant mixture.

The foregoing raw material compounds are compounds containing the respective elements of Zn, Al, Ga, and B, and, for example, oxides, or compounds that decompose and/or oxidize at high temperature to become oxides, such as hydroxides, carbonates, nitrates, halides, sulfates, and salts of organic acids. Examples of applicable compounds containing Zn include zinc oxide (ZnO), zinc hydroxide (Zn(OH)₂), and zinc carbonate (Zn(CO₃)), among which zinc oxide (ZnO) is particularly preferred. Examples of applicable compounds containing Al include aluminum oxide (Al₂O₃), and aluminum hydroxide Al(OH)₃, among which aluminum oxide (Al₂O₃) is particularly preferred. Examples of applicable compounds containing Ga include gallium oxide (Ga₂O₃), and gallium hydroxide (Ga(OH)₃), among which gallium oxide (Ga₂O₃) is particularly preferred. Examples of applicable compounds containing B include boron oxide (B₂O₃), and boric acid (H₃BO₃), among which boron oxide (B₂O₃) is particularly preferred.

The aforementioned mixing may be either dry mixing or wet mixing. A preferred method is one capable of mixing the raw material compounds more evenly and, in this case, examples of applicable mixing devices include devices such as ball mill, V-type mixer, vibrating mill, Attritor, DYNO-MILL, and dynamic mill. Besides the mixing, it is also possible to obtain the mixture by coprecipitation, the hydrothermal technique, the dry up process to evaporate an aqueous solution to dryness, the sol-gel process, and so on.

The complex oxide in the present invention can be obtained by calcining the foregoing mixture. Concerning calcination conditions, a calcination atmosphere is, for example, an inert gas atmosphere such as nitrogen, and the calcination temperature is a temperature of not less than 1000° C. and not more than 1300° C. The calcined product may be pulverized, if necessary, to obtain a pulverized product. The pulverization can be performed using a pulverizer which is normally industrially used, e.g., the ball mill, vibrating mill, Attritor, DYNO-MILL, and dynamic mill.

The complex oxide can be obtained in the stereoscopic shape by sintering the calcined product or the pulverized product. By carrying out the sintering after calcination, it is feasible to improve uniformity of composition in the resultant sintered body, to improve uniformity of crystal structure of the sintered body, and to suppress deformation of the sintered body.

The sintered body made of the complex oxide can also be obtained by sintering the aforementioned mixture, instead of the sintering of the calcined product or the pulverized product.

Concerning sintering conditions, a sintering atmosphere is, for example, an inert gas atmosphere such as nitrogen, and the sintering temperature is a temperature of not less than 1000° C. and not more than 1300° C. A duration of retention at the sintering temperature is, for example, from 5 to 15 hours. The temperature of the sintering is preferably not less than 1150° C. and not more than 1250° C. When the sintering temperature is less than 1000° C., sintering hardly occurs and the value of electrical conductivity (σ) of the resultant sintered body can decrease. Furthermore, when the sintering temperature is over 1300° C., zinc tends to evaporate.

It is preferable to mold the mixture, the calcined product, or the pulverized product, before the sintering. The shaping and the sintering may be carried out simultaneously. The shaping may be carried out in such a manner that a compact is formed in appropriate shape in the thermoelectric conversion module such as the prismatic shape like a rectangular parallelepiped, the platelike shape, or the cylindrical shape, and examples of applicable shaping devices include the uniaxial press, cold isostatic press (CIP), mechanical press, hot press, and hot isostatic press (HIP). A binder, a dispersant, a mold release agent, etc. may be added in the mixture, the calcined product, or the pulverized product.

The foregoing sintered body may be pulverized and the resultant pulverized product may be sintered again as described above.

Each of the above-described calcined product, pulverized product, and sintered body can be used as a thermoelectric conversion material as it is or after it is subjected to a surface treatment such as surface polishing or film coating.

### <Film>

In the thermoelectric conversion material of the present invention, at least a part of the surface of the complex oxide may be coated with a film. When the surface of the complex oxide is coated with a film, the film can prevent evaporation of Zn in the thermoelectric conversion material in a high-temperature atmosphere. Furthermore, it can prevent degradation of characteristics of the thermoelectric conversion material, for example, even if the used atmosphere of the thermoelectric conversion material is an atmosphere easy to oxidize the complex oxide, e.g., an oxidizing gas such as air. The film is preferably one containing at least one of silica, alumina, and silicon carbide as a major ingredient.

The thickness of the film is preferably in the range of from 0.01 μm to 1 mm, more preferably in the range of from 0.1 μm to 300 μm, and still more preferably in the range of from 1 μm to 100 μm. If the thickness of the film is too small, it is hard to achieve the aforementioned effect of the film; if the thickness of the film is too large, the film becomes easier to crack.

### <Relative Density>

When the thermoelectric conversion material of the present invention is used in the form of the sintered body, the density of the complex oxide, as relative density, is preferably not less than 95%, more preferably not less than 97%, and still more preferably not less than 98%, in terms of ensuring the strength of the thermoelectric conversion material. If the relative density is less than 95%, the value of electric conductivity (σ) tends to decrease. The density of the complex oxide can be controlled by particle size of the mixture, the calcined product, or the pulverized product, molding pressure in manufacture of the compact, temperature of sintering, time of sintering, and so on.

The relative density can be determined by the formula below, where β (g/cm³) is the theoretical density of the complex oxide and γ (g/cm³) measured density. The measured density can be obtained by the Archimedes method.

Relative density (%)=γ/β×100

### <Thermoelectric Conversion Module>

The thermoelectric conversion module will be described below. The thermoelectric conversion module of the present invention comprises a plurality of n-type thermoelectric conversion materials; a plurality of p-type thermoelectric conversion materials; and a plurality of electrodes electrically serially connecting the plurality of p-type thermoelectric conversion materials and the plurality of n-type thermoelectric conversion materials in an alternate arrangement, and at least one material of the plurality of n-type thermoelectric conversion materials is the aforementioned thermoelectric conversion material of the present invention.

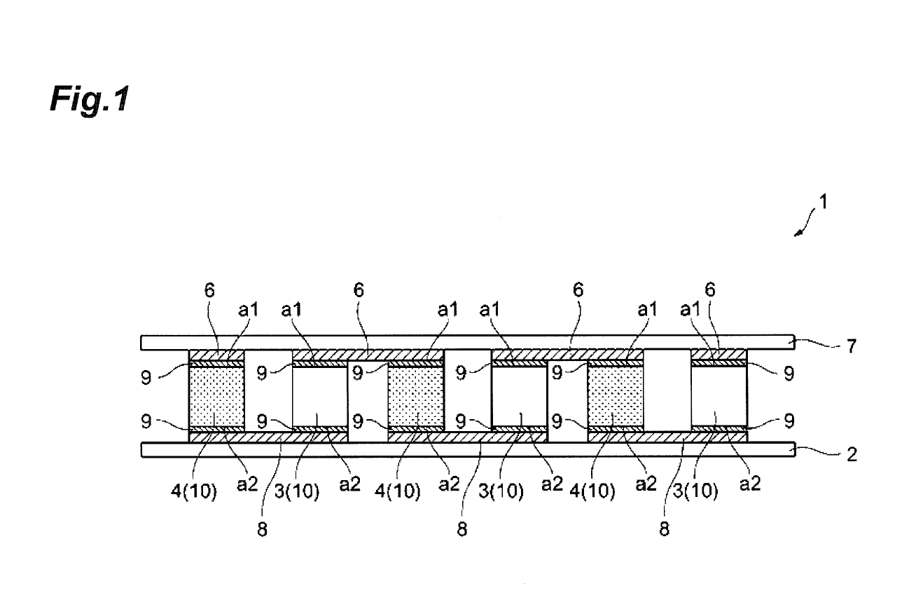

The below will describe an embodiment of the thermoelectric conversion module using the thermoelectric conversion materials. FIG. 1 is a cross-sectional view of thermoelectric conversion module 1 using thermoelectric conversion materials 10. As shown in FIG. 1, the thermoelectric conversion module 1 is provided with a first substrate 2, first electrodes 8, thermoelectric conversion materials 10, second electrodes 6, and a second substrate 7.

The first substrate 2 has, for example, a rectangular shape, has electrical insulation and thermal conductivity, and covers one end faces of the thermoelectric conversion materials 10. A material of this first substrate is, for example, alumina, aluminum nitride, or magnesia.

The first electrodes 8 are provided on the first substrate 2 and electrically connect one end faces of mutually adjacent thermoelectric conversion materials 10 to each other. The first electrodes 8 can be formed at prescribed positions on the first substrate 2, for example, by a method such as the thin-film technology, e.g., sputtering or evaporation, screen printing, plating, or thermal spraying. The electrodes 8 may be formed by joining metal plates or the like of prescribed shape onto the first substrate 2, for example, by a method such as soldering or brazing. There are no particular restrictions on a material of the first electrodes 8 as long as it is an electrically conductive material. In terms of improving the heat resistance, corrosion resistance, and adhesion of the electrodes to the thermoelectric conversion materials, the material of the electrodes is preferably a metal containing at least one element selected from the group consisting of titanium, vanadium, chromium, manganese, iron, cobalt, nickel, copper, molybdenum, silver, palladium, gold, tungsten, and aluminum, as a major ingredient. The major ingredient herein means an ingredient that is contained 50% by volume or more in the electrode material.

The second substrate 7 has, for example, a rectangular shape and covers the other end faces of the thermoelectric conversion materials 10. The second substrate 7 is opposing to and in parallel with the first substrate 2. There are no particular restrictions on a material of the second substrate 7 as long as it is an electrically insulating and thermally conductive material, as the first substrate 2 is. The material can be, for example, alumina, aluminum nitride, or magnesia.

The second electrodes 6 electrically connect the other end faces of mutually adjacent thermoelectric conversion materials 10 to each other. The second electrodes 6 can be formed at prescribed positions on the lower surface of the second substrate 7, for example, by a method such as the thin-film technology, e.g., sputtering or evaporation, screen printing, plating, or thermal spraying. The thermoelectric conversion materials 10 are electrically connected in series by the first electrodes 8 and the second electrodes 6.

The p-type thermoelectric conversion materials 3 and the n-type thermoelectric conversion materials 4 are arranged in an alternate arrangement between the first substrate 2 and the second substrate 7. The both end faces of these thermoelectric conversion materials are joined to be fixed to the surfaces of the first electrodes 8 and the second electrodes 6 corresponding to the respective faces, for example, with joint materials 9 such as an AuSb or PbSb type solder or a silver paste, and all the p-type thermoelectric conversion materials 3 and n-type thermoelectric conversion materials 4 are electrically connected in series in the alternate arrangement. The joint materials are preferably materials that are solid during use of the thermoelectric conversion module.

As described above, the both end faces a1, a2 of the plurality of p-type thermoelectric conversion materials 3 and n-type thermoelectric conversion materials 4 forming the thermoelectric conversion module 1 are opposing to the respective electrodes 6, 8 and are joined to the electrodes 6, 8, for example, through the respective joint materials 9.

The thermoelectric conversion material of the present invention is suitably used as the n-type thermoelectric conversion materials 4 in the thermoelectric conversion module. A material of the p-type thermoelectric conversion materials 3 can be, for example, a complex oxide such as NaCO₂O₄ or Ca₃CO₄O₉, a silicide such as MnSi_{1.73}, Fe₁₋ₓMnₓSi₂, Si_{0.8}Ge_{0.2}, or β-FeSi₂, a skutterudite such as CoSb₃, FeSb₃, or RFe₃CoSb₁₂ (where R represents La, Ce or Yb), an alloy containing Te such as BiTeSb, PbTeSb, Bi₂Te₃, or PbTe. Among these, the p-type thermoelectric conversion materials 3 preferably contain the foregoing complex oxide.

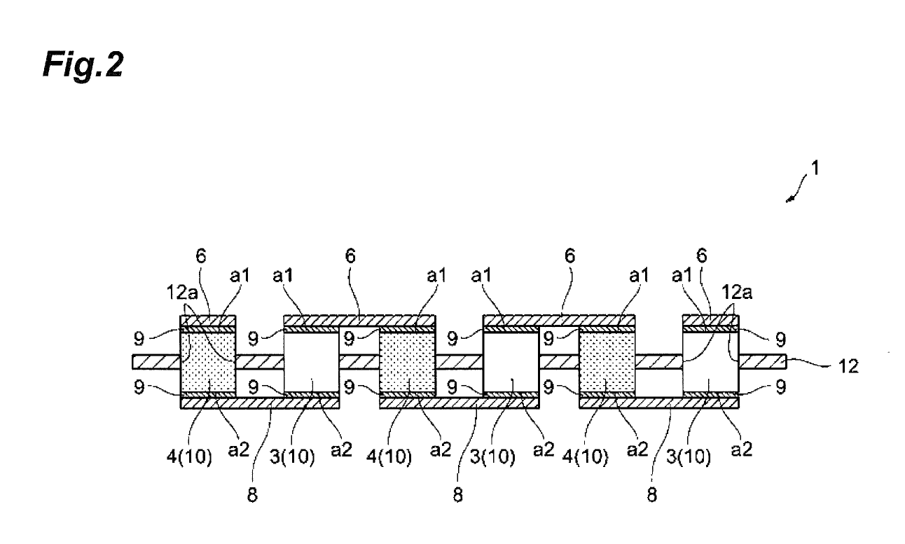

The thermoelectric conversion module does not have to be limited to the above embodiment. FIG. 2 shows a cross-sectional view of an example of skeleton type thermoelectric conversion module 1 using the thermoelectric conversion materials 10. FIG. 2 is different from FIG. 1 in that the thermoelectric conversion module 1 does not have the pair of substrates 2, 7 opposing to each other but is provided with a support frame 12, instead of them. The support frame 12 is interposed between the plurality of thermoelectric conversion materials 10 and located so as to surround central portions in the height direction of the respective thermoelectric conversion materials 10, and secures each of the thermoelectric conversion materials at an appropriate position. The other configuration is the same as that of the thermoelectric conversion module shown in FIG. 1.

The support frame 12 has thermal insulation and electrical insulation and, through holes 12a corresponding to the positions where the respective thermoelectric conversion materials 10 are to be located are formed in this support frame 12. The through holes 12a have a shape corresponding to the cross-sectional shape of the thermoelectric conversion materials 3, 4, e.g., a shape such as square or rectangular shape.

The thermoelectric conversion materials 10 are fitted in the respective through holes 12a. Since the space between internal wall faces of each through hole 12a and the side faces of each thermoelectric conversion material 10 is very narrow, the support frame 12 can fix the plurality of thermoelectric conversion materials 10. The internal wall faces of the through holes 12a may be filled with an adhesive or the like, if necessary, so as to fix the thermoelectric conversion materials 10 more firmly. In this manner, the thermoelectric conversion materials 10 are fixed by the support frame 12.

There are no particular restrictions on a material of the support frame 12 as long as it has thermal insulation and electrical insulation. The material of the support frame 12 can be, for example, a resin material or a ceramic material. The material of the support frame 12 may be suitably selected from materials that do not melt at an operating temperature of the thermoelectric conversion module 1. For example, when the operating temperature is around room temperature, the material may be polypropylene, ABS, polycarbonate, or the like; when the operating temperature is around from room temperature to 200° C., the material may be a super engineering plastic such as polyamide, polyimide, polyamide-imide, or polyether ketone; when the operating temperature is not less than about 200° C., the material may be a ceramic material such as alumina, zirconia, or cordierite. These materials may be used singly or in combination of two or more.

In the above-described skeleton type thermoelectric conversion module, different from the thermoelectric conversion module shown in FIG. 1, the plurality of thermoelectric conversion materials 10 and the plurality of electrodes 6, 8 are not sandwiched in between the substrates 2, 7. Therefore, the skeleton type thermoelectric conversion module can reduce thermal stress acting on each thermoelectric conversion material 10 and can reduce contact thermal resistance.

### EXAMPLES

The present invention will be described below in further detail using examples.

### Example 1

### Zn:Al:Ga:B=0.959:0.02:0.02:0.001

A ZnO powder (available from Kojundo Chemical Laboratory Co., Ltd.), an Al₂O₃ powder (available from Kojundo Chemical Laboratory Co., Ltd.), a Ga₂O₃ powder (available from Kojundo Chemical Laboratory Co., Ltd.), and a B₂O₃ powder (available from Kojundo Chemical Laboratory Co., Ltd.) were weighed so that the molar ratio of Zn:Al:Ga:B became 0.959:0.02:0.02:0.001. These were put together with ethanol and ZrO₂ balls into a resin pot, and they were mixed by a ball mill for twenty hours, and dried to obtain a mixture. This mixture was molded in a rectangular parallelepiped shape by uniaxial press using a die, and was further pressed under the pressure of 1800 kgf/cm² for one minute by isostatic press using a press machine (CIP available from KOBELCO) to obtain a compact. The resultant compact was sintered by holding it at 1200° C. in a nitrogen atmosphere for ten hours.

The resultant sintered body made of the complex oxide was deep blue. The surface resistance of the sintered body was measured with a multimeter and the resistance was found to be 0.6Ω. Furthermore, the surface of the sintered body was polished using sandpapers of #240, #400, and #1000 in this order. The surface resistance of the sintered body after the polishing was measured and the resistance was found to be 0.6Ω, showing no change in resistance before and after the polishing. The thermoelectric conversion characteristic of the sintered body was evaluated with a thermoelectric characteristic evaluator (ZEM-3 available from ULVAC-RIKO, Inc.). The value of power factor (α²×σ) at 760° C. was 7.6×10⁻⁴ W/mK⁻², confirming that the material was useful as a thermoelectric conversion material. The relative density of the complex oxide was 98.6%. While the relative density was high, the thermal conductivity (κ) at 760° C. was an extremely small value of 6.5 W/mK and the performance index (Z) was an extremely large value of 1.2×10⁻⁴K⁻¹.

### Comparative Example 1

### Zn:Al:Ga=0.96:0.02:0.02

A ZnO powder (available from Kojundo Chemical Laboratory Co., Ltd.), an Al₂O₃ powder (available from Kojundo Chemical Laboratory Co., Ltd.), and a Ga₂O₃ powder (available from Kojundo Chemical Laboratory Co., Ltd.) were weighed so that the molar ratio of Zn:Al:Ga became 0.96:0.02:0.02. These were put together with ethanol and ZrO₂ balls into a resin pot, and they were mixed by a ball mill for twenty hours and dried to obtain a mixture. This mixture was molded in a rectangular parallelepiped shape by uniaxial press using a die and was pressed under the pressure of 1800 kgf/cm² for one minute by isostatic press using a press machine (CIP available from KOBELCO) to obtain a compact. The resultant compact was sintered by holding it at 1200° C. in a nitrogen atmosphere for ten hours.

The resultant sintered body made of the complex oxide was slightly whitish blue. The surface resistance of the sintered body was measured with the multimeter and the resistance was found to be 0.6Ω. The surface of the sintered body was polished in the same manner as in Example 1 and the surface resistance of the sintered body after the polishing was found to be about 1000Ω, showing an increase in the surface resistance due to the polishing. The value of power factor (α²×σ) at 760° C. was 6.4×10⁻⁴ W/mK⁻², which was smaller than the value of power factor in Example 1. The relative density of the complex oxide was 95.3%. The thermal conductivity (κ) at 760° C. was a large value of 11.3 W/mK and the performance index (Z) a small value of 0.57×10⁻⁴K⁻¹.

### Example 2

### Zn:Al:Ga:B=0.9599:0.02:0.02:0.0001

A sintered body made of a complex oxide was obtained in the same manner as in Example 1, except that the powders were weighed so that the molar ratio of Zn:Al:Ga:B became 0.9599:0.02:0.02:0.0001.

The surface resistance of the sintered body was measured with the multimeter and the resistance was found to be 0.6Ω. The surface of the sintered body was polished in the same manner as in Example 1 and the surface resistance of the sintered body after the polishing was found to be 0.6Ω, showing no change in resistance before and after the polishing. The thermoelectric conversion characteristic of the sintered body was evaluated with the thermoelectric characteristic evaluator (ZEM-3 available from ULVAC-RIKO, Inc.). The value of power factor (α²×σ) at 760° C. was 7.2×10⁻⁴ W/mK⁻². The relative density of the complex oxide was 98.0%.

### Example 3

### Zn:Al:Ga:B=0.95:0.02:0.02:0.01

A sintered body made of a complex oxide was obtained in the same manner as in Example 1, except that the powders were weighed so that the molar ratio of Zn:Al:Ga:B became 0.95:0.02:0.02:0.01.

The surface resistance of the sintered body was measured with the multimeter and the resistance was found to be 0.6Ω. The surface of the sintered body was polished in the same manner as in Example 1 and the surface resistance of the sintered body after the polishing was found to be 0.6Ω, showing no change in resistance before and after the polishing. The thermoelectric conversion characteristic of the sintered body was evaluated with the thermoelectric characteristic evaluator (ZEM-3 available from ULVAC-RIKO, Inc.). The value of power factor (α²×σ) at 760° C. was 5.6×10⁻⁴ W/mK⁻². Furthermore, the relative density of the complex oxide was 99.0%.

### INDUSTRIAL APPLICABILITY

The present invention allows us to obtain the thermoelectric conversion material having the small value of surface resistance, being resistant to increase in surface resistance during processing, and having the large value of power factor. Since the value of thermal conductivity becomes small, we can obtain the thermoelectric conversion material with an extremely large performance index. When this thermoelectric conversion material is applied to the n-type thermoelectric conversion materials in the thermoelectric conversion module, it is feasible to provide efficient thermoelectric power generation. In addition, the thermoelectric conversion material of the present invention can be obtained by sintering at relatively low temperature, and therefore the present invention is extremely useful industrially.

1. A thermoelectric conversion material comprising:
a complex oxide containing Zn, Al, Ga, and B.

2. The thermoelectric conversion material according to claim 1, wherein the ratio of a molar amount of B to a total molar amount of Zn, Al, Ga, and B is not less than 0.0001 and not more than 0.01.

3. The thermoelectric conversion material according to claim 1, wherein the ratio of a molar amount of Al to a total molar amount of Zn, Al, Ga, and B is not less than 0.001 and not more than 0.1.

4. The thermoelectric conversion material according to claim 1, wherein the ratio of a molar amount of Ga to a total molar amount of Zn, Al, Ga, and B is not less than 0.001 and not more than 0.1.

5. The thermoelectric conversion material according to claim 1, wherein the relative density of the complex oxide is not less than 95%.

6. The thermoelectric conversion material according to claim 1, wherein at least a part of a surface of the complex oxide is coated with a film.

7. A thermoelectric conversion module comprising:
a plurality of n-type thermoelectric conversion materials;
a plurality of p-type thermoelectric conversion materials; and
a plurality of electrodes electrically serially connecting the plurality of p-type thermoelectric conversion materials and the plurality of n-type thermoelectric conversion materials in an alternate arrangement,
wherein at least one material of the plurality of n-type thermoelectric conversion materials is the thermoelectric conversion material according to claim 1.
